(19) United States
(12) Patent Application Publication
(10) Pub. No.: US 2014/0030447 A1
(43) Pub. Date: Jan. 30, 2014

(54) Deposition of Graphene or Conjugated Carbons Using Radical Reactor

(71) Applicant: Synos Technology, Inc., Fremont, CA (US)

(72) Inventors: Sang In Lee, Sunnyvale, CA (US); Chang Wan Hwang, Busan (KR)

(73) Assignee: Synos Technology, Inc., Fremont, CA (US)

(21) Appl. No.: 13/742,148

(22) Filed: Jan. 15, 2013

Related U.S. Application Data
(60) Provisional application No. 61/587,555, filed on Jan. 17, 2012.

(51) Int. Cl. C23C 16/26

(52) U.S. Cl. CPC C23C 16/26
USPC 427/577; 427/249.1; 118/723 E

(57) ABSTRACT

Depositing a layer of graphene or conjugate carbons on a surface of a substrate using carbon radicals generated by exposing a carbon material to radicals of a gas. The radicals of the gas are generated by injecting the gas into a plasma chamber and then applying voltage difference to electrodes within or surrounding the plasma chamber. The radicals of the gas come into contact with the carbon material (e.g., graphite) and excite carbon radicals. The excited carbon radicals are injected onto the surface of the substrate, passes through a constriction zone of the reactor assembly and are then exhausted through a discharge portion of the reactor assembly. When the excited carbon radicals come into contact with the substrate, the carbon radicals form a layer of graphene or conjugated carbons on the substrate.

### CROSS-REFERENCE TO RELATED APPLICATION

This application claims the benefit under 35 U.S.C. §119(e) to U.S. Patent Application Ser. No. 61/587,555 entitled “Deposition of Graphene Using Plasma Reactor” filed on Jan. 17, 2012, which is incorporated by reference herein in its entirety.

### BACKGROUND

The present disclosure relates to deposition of a layer of graphene or conjugated carbons on a substrate using a radical reactor.

Graphene is an allotrope of carbon that is densely packed into a flat honeycomb crystal lattice structure. Graphene has various advantageous properties that render it as a choice of material in electronic devices. One of the advantageous properties is the excellent electrical conductive property derived from its unique structure. Due to its unique structure, graphene allows charge carriers (electrons) to travel at a much higher speed than in a semiconductor. Moreover, graphene is very thin, strong, transparent and flexible.

However, the method of making graphene is an expensive and time consuming process. One way of making a layer of graphene is by heating silicon carbide wafers in a vacuum so that the silicon is vaporized, leaving behind the carbon atoms. This method is too expensive to commercially fabricate graphene. Another way of fabricating graphene is by using chemical vapor deposition in which graphene is grown by depositing hot hydrocarbon gases on a reactive metal surface. Finally, the graphene can be fabricated by directly exfoliating graphene in solution using ultrasound or specialized solvents such as ionic waters.

### SUMMARY

Embodiments relate to depositing a layer of graphene or conjugated carbons on a substrate by exposing carbon material to radicals of a gas to generate carbon radicals. The carbon radicals come in contact with the substrate and become deposited on the substrate as a layer of graphene or conjugated carbons. The gas is injected into a plasma chamber with electrodes that are applied with an electrical voltage signal to generate the radicals of the gas.

In one embodiment, the gas includes an oxygen compound.

In one embodiment, the gas further includes inert gas.

In one embodiment, the carbon material includes graphite.

In one embodiment, the conjugated carbons include at least one of graphyne, graphane, graphene oxide and carbon nanotubes.

In one embodiment, excess carbon radicals remaining after exposing to the part of the surface of the substrate are discharged.

In one embodiment, gas is injected into a plasma chamber defined by a first electrode and a second electrode. A voltage difference is applied across the first electrode and the second electrode to generate the radicals of the gas.

In one embodiment, the temperature of the substrate is controlled to 100° C. to 500° C.

In one embodiment, a layer of aluminum oxide is deposited on the surface and a layer of graphene or conjugated carbons is deposited on the layer of aluminum oxide.

### BRIEF DESCRIPTION OF DRAWINGS

FIG. 1 is a cross sectional diagram of a linear deposition device, according to one embodiment.

FIG. 2 is a perspective view of a linear deposition device, according to one embodiment.

FIG. 3 is a perspective view of a rotating deposition device, according to one embodiment.

FIG. 4 is a perspective view of a radical reactor for depositing a layer of graphene or conjugated carbons, according to one embodiment.

FIG. 5 is a cross sectional diagram of the radical reactor taken along line A-B of FIG. 4, according to one embodiment.

FIG. 6 is a cross sectional diagram of a radical reactor, according to another embodiment.

FIG. 7 is a cross sectional diagram of a radical reactor, according to another embodiment.

FIG. 8 is a cross sectional diagram of a stacked structure including aluminum oxide layers and graphene layers, according to one embodiment.

FIG. 9 is flowchart illustrating a process of depositing a layer of graphene or conjugated carbons, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to depositing a layer of graphene or conjugated carbons on a surface of a substrate using carbon radicals generated by exposing a carbon material to radicals of a gas. The radicals of the gas are generated by injecting the gas into a plasma chamber and then applying voltage difference to electrodes within or surrounding the plasma chamber. The radicals of the gas generated in the plasma chamber come into contact with the carbon material (e.g., graphite) and excite carbon radicals. The excited carbon radicals are injected onto the surface of the substrate, passes through a constriction zone of the reactor assembly and are then exhausted through a discharge portion of the reactor assembly. When the excited carbon radicals come into contact with the substrate, a layer of graphene or conjugated carbons is deposited on the substrate.

Conjugated carbons herein refer to carbon chains containing an alternation of single and multiple bonds. Example conjugated carbons include graphyne, graphane, graphene oxide and carbon nanotubes.

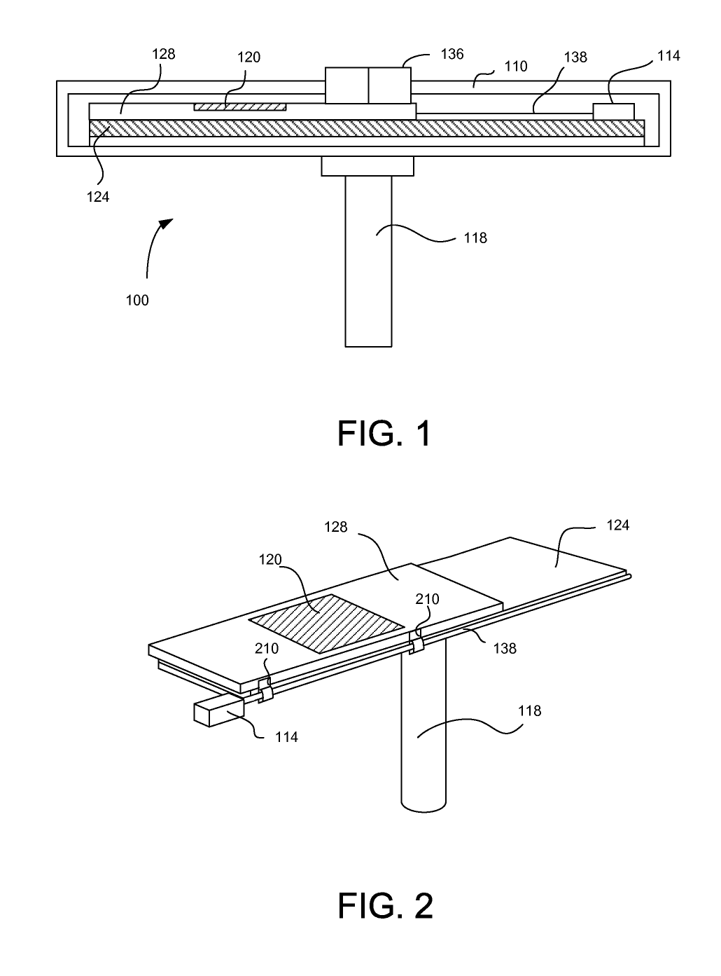

FIG. 1 is a cross sectional diagram of a linear deposition device 100 according to one embodiment. FIG. 2 is a perspective view of the linear position device 100 (without chamber walls 110 to facilitate explanation) of FIG. 1. The linear deposition device 100 may include, among other components, a support pillar 118, a process chamber 110 and a reactor assembly 136. The reactor assembly 136 may include one or more of injectors and radical reactors. Each of the injector modules injects source precursors, reactant precursors, purge gases or a combination of these materials onto the substrate 120. The radical reactors inject radicals onto the substrate 120. The radicals may function as source precursors, reactant precursors or material deposited on the surface of the substrate 120.

The process chamber enclosed by the walls 110 may be maintained in a vacuum state to prevent contaminants from affecting the deposition process. The process chamber contains a susceptor 128 which receives a substrate 120. The susceptor 128 is placed on a support plate 124 for a sliding movement. The support plate 124 may include a temperature controller (e.g., a heater or a cooler) to control the temperature of the substrate 120. The linear deposition device 100 may also include lift pins (not shown) that facilitate loading of the substrate 120 onto the susceptor 128 or dismounting of the substrate 120 from the susceptor 128.

In one embodiment, the susceptor 128 is secured to brackets 210 that move across an extended bar 138 with screws formed thereon. The brackets 210 have corresponding screws formed in their holes receiving the extended bar 138. The extended bar 138 is secured to a spindle of a motor 114, and hence, the extended bar 138 rotates as the spindle of the motor 114 rotates. The rotation of the extended bar 138 causes the brackets 210 (and therefore the susceptor 128) to make a linear movement on the support plate 124. By controlling the speed and rotation direction of the motor 114, the speed and direction of the linear movement of the susceptor 128 can be controlled. The use of a motor 114 and the extended bar 138 is merely an example of a mechanism for moving the susceptor 128. Various other ways of moving the susceptor 128 (e.g., use of gears and pinion at the bottom, top or side of the susceptor 128) may be used. Moreover, instead of moving the susceptor 128, the susceptor 128 may remain stationary and the reactor 136 may be moved.

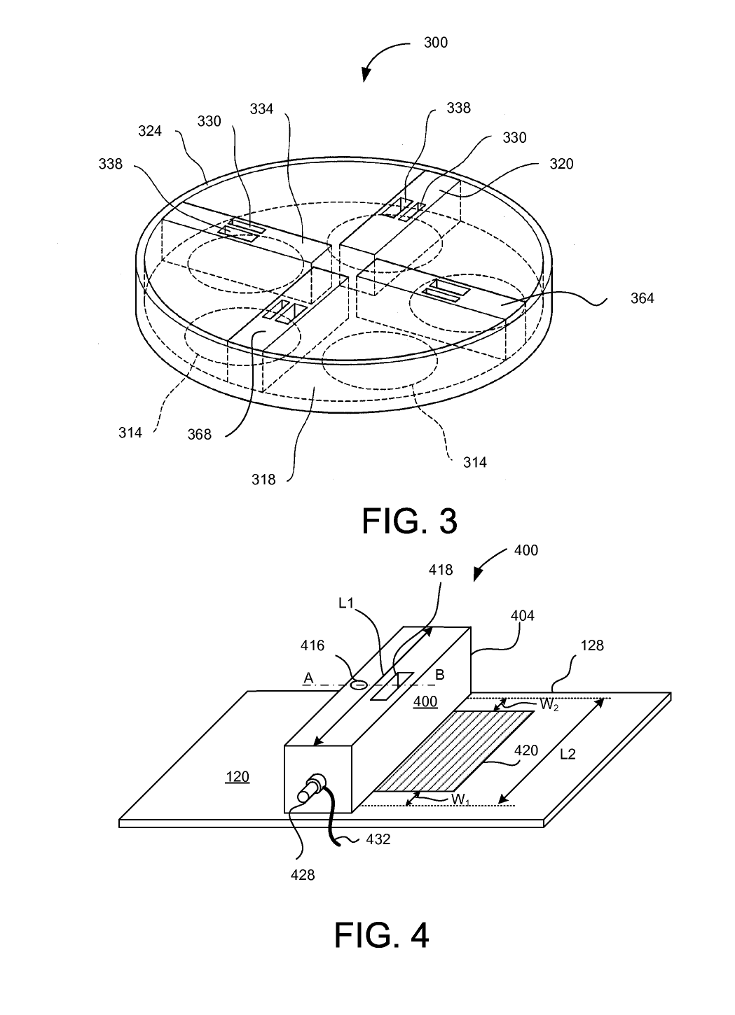

FIG. 3 is a perspective view of a rotating deposition device 300, according to one embodiment. Instead of using the linear deposition device 100 of FIG. 1, the rotating deposition device 300 may be used to perform the deposition process according to another embodiment. The rotating deposition device 300 may include, among other components, reactors 320, 334, 364, 368 (collectively referred to as the “reactor assembly” herein), a susceptor 318, and a container 324 enclosing these components. The susceptor 318 secures the substrates 314 in place. The reactor assembly is placed above the substrates 314 and the susceptor 318. Either the susceptor 318 or the reactor assembly rotates to subject the substrates 314 to different processes.

One or more of the reactors 320, 334, 364, 368 are connected to gas pipes via inlet 330 to receive source precursor, reactor precursor, purge gas and/or other materials. The materials provided by the gas pipes may be (i) injected onto the substrate 314 directly by the reactors 320, 334, 364, 368, (ii) after mixing in a chamber inside the reactors 320, 334, 364, 368, or (iii) after conversion into radicals by plasma generated within the reactors 320, 334, 364, 368. After the materials are injected onto the substrate 314, the redundant materials may be exhausted through outlets 330.

Embodiments of reactor assembly described herein can be used in deposition devices such as the linear deposition device 100, the rotating deposition device 300 or other types of deposition devices.

FIG. 4 is an example of a radical reactor 400 in a reactor assembly 136, according to one embodiment. Although only reactor assembly 136 is illustrated in FIG. 4, the reactor assembly 136 may include injectors (for injecting gas onto the substrate 120) and/or other radical reactors. The radical reactor 400 is elongated to cover at least part of the substrate 120. The susceptor 128 mounted with the substrate 120 may reciprocate in two directions (i.e., right and left directions in FIG. 4) to expose the substrate 120 to radicals injected by the reactor assembly 400.

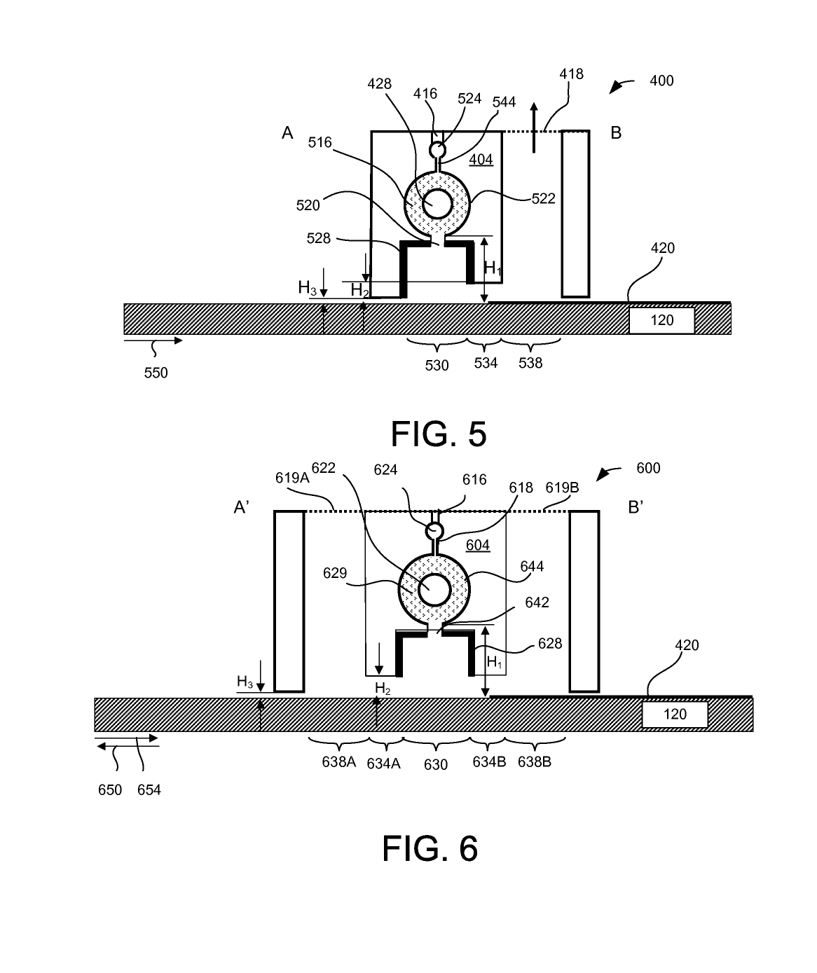

The radical reactor 400 receives gas via an inlet 416 for generating radicals. Channels are formed in the body 404 of the radical reactor 400 to convey the received gas to a plasma chamber. An inner electrode extends across the radical reactor 400 and is connected to a voltage source (not shown) or ground (not shown) via wires 432. The inner electrode is placed inside the plasma chamber, as described below in detail with reference to FIG. 5. The outer electrode in the radical reactor 400 is connected to ground or a voltage source. In one embodiment, the conductive body of the radical reactor 400 functions as the outer electrode. An outlet 418 is formed in the body 404 of the radical reactor 400 to discharge excess radicals and/or gases (reverted to an inactive state from the radicals during, before or after being injected onto the substrate 120 out of the deposition device 100). The outlet 418 is connected to a pipe (not shown) to discharge the excess radicals and/or gases outside the linear deposition device 100.

As illustrated in FIG. 4, the effective length L2 of the reactor assembly is longer by W₁+W₂ than the width of the substrate 120. The effective length L2 refers to the length across the reactor assembly where a layer of graphene or conjugated carbons 420 is deposited on the substrate 120 with a predefined level of quality. The predetermined level of quality may be represented as characteristics or properties of the graphene or conjugated carbons 420 deposited on the substrate 120. Because the deposition is not performed in a uniform and consistent manner at the side edges of the reactor assembly, the effective length tends to be shorter than the actual length L1 of the reactor assembly.

Inert gas or other gases may be injected into the radical reactor 400 via inlet 416. For example, (i) inert gas such as Ar, Ne and He, (ii) inert gas in combination with N₂O (e.g., 0 to 50%) or (iii) inert gas in combination with N₂O (0 to 30%) and C₂H₂ (0 to 30%) may be injected into the radical reactor 400. In one or more embodiments, direct current (DC) pulses of 150 kHz to 350 kHz having 20 to 80% duty cycle was applied to the electrodes 428, 522 at 100 W through 300 W to generate the plasma in the plasma chamber 516. The temperature of the substrate may be controlled to 100° C. to 500° C.

FIG. 5 is a cross sectional diagram of the radical reactor 400 taken along line A-B of FIG. 4, according to one embodiment. The injector 402 has a body 404 with an inlet 416 and an outlet 412 formed therein.

A gas is injected into the radical reactor 400 via the inlet 416, flows through the channel 524 and slits or holes 544 into the plasma chamber 516. The gas injected into the radical reactor 400 may be inert gas (e.g., Argon) or a combination of hydrocarbon (e.g., C₂H₂), inert gas and other gases such as N₂O, N₂ in combination with O₂, and O₃. The plasma of hydrocarbon gas may enhance the population of carbon radicals which promotes the formation of graphene or conjugated carbons. Oxygen included in the gas oxygen reacts with undesirable carbon compounds and removes them from the substrate 120. In this way, the stability and property of the graphene layer or conjugated carbons 420 can be enhanced. On the other hand, it is beneficial to prevent hydrogen-compound gases such as H₂ and NH₃ from being injected into the radical reactor 400 to avoid hydrogen binding from being introduced into the layer 420 of graphene layer or conjugated carbons. If the target deposition material is graphane instead of graphene, hydrogen-compound gases such as H₂ and NH₃ can be injected into the radical reactor 400.

As the voltage difference is applied between the inner electrode 428 and the outer electrode 522, plasma is generated in the radical chamber 516. As a result, radicals of the injected gas are formed in the radical chamber 516 and injected into a reaction zone 530 via slits or holes 520. Carbon materials such as graphite linings 528 are placed in the reaction region 530 so that carbon radicals are generated when the radicals of gas are injected into the reaction zone 530 and come into contact with the carbon materials. When the radicals of gas come into contact with the carbon materials, energy of the radicals of the gas is transferred to carbon atoms in the carbon material, causing excitation and emission of carbon radicals from the carbon material. The emitted carbon radicals then come in contact with the moving substrate 120 and form a layer 420 of graphene or conjugated carbons on its surface. The substrate 210 may move with a speed of 50 mm/sec to 250 mm/sec but different speed may be used depending on other relevant parameters.

In one embodiment, the radical chamber 516 is placed at a distance of H₁ from the substrate 120. H₁ may be sufficiently large so that the plasma generated in the radical chamber 516 or high voltage in the electrodes does not affect the integrity of the substrate 120.

The remaining carbon radicals and the radicals of the gas pass through a constriction zone 534 having a height H₂ and communicating with reaction zone 530 and exhaust zone 538. The speed or gas/radical flow increases in the constriction zone 534 and results in a lower pressure than in the reaction zone 530. Such high speed and low pressure facilitates the removal of any excess carbon atoms from the surface of the substrate 120. The radical reactor 400 is separated from the substrate 120 by a clearance of H₃ which is smaller than H₂. In one embodiment, the clearance H₃ is smaller than 20% of the clearance H₂. Hence, most of the gas/radicals are discharged through the exhaust zone 538. The exhaust zone 538 is connected to the outlet 418 to discharge the excess gas/radicals. In one embodiment, H₁, H₂, H₃ are set to 20 mm, 5 mm, and 1 mm, respectively.

In the embodiment of FIG. 5, it is advantageous to move the substrate 120 in direction 550 since the substrate 120 is first exposed to carbon radicals at a higher density and energy. That is, the density of the radicals and the energy level of the carbon radicals are the highest in the reaction zone 530. As the carbon radicals travel to the constriction zone 534 and the exhaust zone 538, the carbon radicals form graphene or conjugated carbons on the surface of the substrate 120. Exposing the substrate 120 first to the carbon radicals in the reaction zone 530 advantageously promotes the deposition of graphene or conjugated carbons on the substrate 120 since the density of the carbon radicals is the highest in the reaction zone 530.

The formation of a layer of graphene or conjugated carbons can be controlled, for example, by adjusting the speed of substrate 120 below the radical reactor 400, the dimensions of the radical reactor (e.g., heights of H₁ and H₂, widths of slits or holes 520, the length of the reaction zone 530, and the length of the constriction zone 534), the mixture ratio of gases (e.g., the mixture ratio of Ar, N₂O and C₂H₂), exhaust conditions (e.g., pressure level at the outlet 418) and conditions for generating the plasma (e.g., voltage difference across the two electrodes, duty cycle as the ratio between the pulse duration, and the period of a DC pulse).

FIG. 6 is a cross sectional diagram of a radical reactor 600, according to another embodiment. The radical reactor 600 has a symmetric structure where its body 604 has two outlets 619A, 619B formed at both sides of a reaction zone 630. The gas is injected into the plasma chamber 629 via an inlet 616, a channel 624 (extending in longitudinal direction), and holes or slits 618. Plasma is generated in the plasma chamber 629 by applying voltage difference across an inner electrode 622 and an outer electrode 644. In one embodiment, the duty cycle of the pulses is 20 to 80%. As a result, the radicals of the gas is generated and injected into a reaction zone 630 via holes or slits 642.

The plasma chamber 629 is separated from the substrate 120 by a distance of H₁. Within the reaction zone 630, the radicals of the gas come into contact with carbon lines 628 and generate carbon radicals. The carbon radicals form a layer 420 of graphene or conjugated carbons by coming into contact with the substrate 120 below the reaction zone 630.

The remaining gas or radicals flow through constriction zones 634A, 638B (having height of H₂) into exhaust zones 638A, 638B (although small quantities of gas or radicals are leaked out via clearance H₃). Then the remaining gas or radicals are discharged via the outlets 619A, 619B.

As illustrated in FIG. 6, the substrate 120 may reciprocate in both directions 650, 654. If the plasma is active in the radical reactor 600, an additional layer of graphene or conjugated carbons is deposited on the substrate 120 with each passing of the substrate 120 below the radical reactor 600.

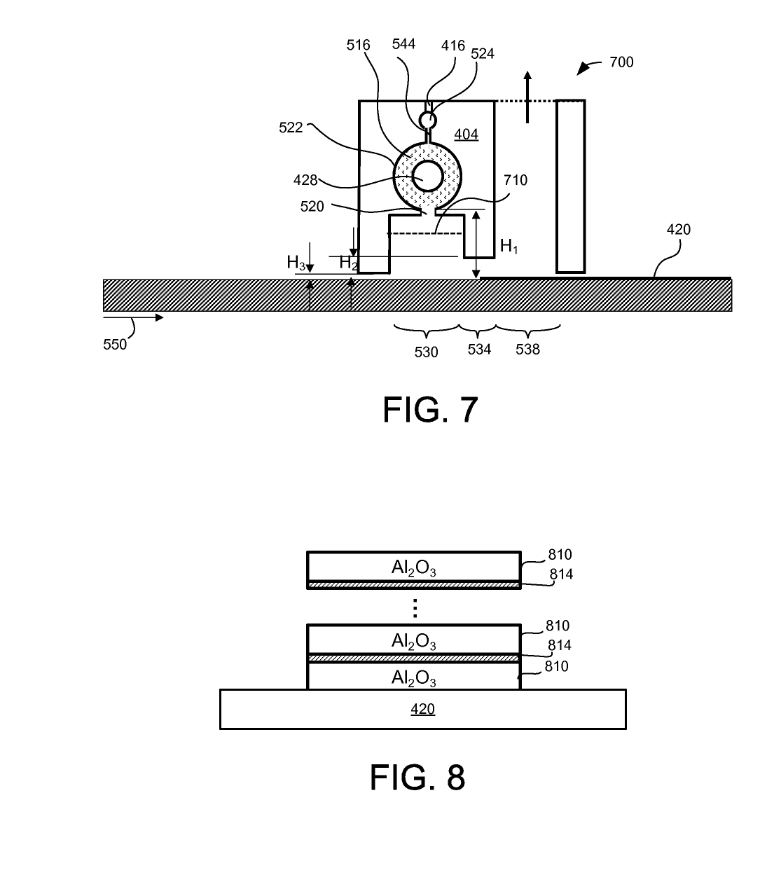

FIG. 7 is a cross sectional diagram of a radical reactor 700, according to another embodiment. The embodiment of FIG. 7 is the same as the embodiment of FIG. 5 except that a mesh or plate 710 of carbon materials (e.g., carbon fiber or graphite mesh) is installed in the reaction zone 530 instead of the carbon linings 528 of FIG. 5. As the radicals of the gas passes through the mesh or plate 710, carbon atoms are excited and carbon radicals are emitted from the mesh or plate 710. The carbon materials may be placed at various different places within the reaction zone 530 in various other forms.

FIG. 8 is a cross sectional diagram of a stacked structure including aluminum oxide (Al₂O₃) layers 810 and graphene layers 814, according to one embodiment. Aluminum oxide has a band gap of 8.8 eV and current-voltage characteristics attributable to Fowler-Nordheim (FN) tunneling effect. Further, aluminum oxide is transparent even in ultra-violet (UV) wavelength region, and exhibit low leakage current characteristics in regions where the tunneling effect is not experienced. Due to such characteristics, aluminum oxide is often used as dielectric materials in semiconductor devices or gas barriers for encapsulating organic light emitting diode (OLED) devices. Although the following embodiments and FIG. 8 are described with reference to using aluminum oxide as the dielectric material, other structures may also be formed by depositing a layer of graphene or conjugated carbons on different materials.

A deposition device such as the linear deposition device 100 or the rotational deposition device 300 may be used to deposit the structure of FIG. 8. The deposition device may include, among other components, injectors and/or radical reactors for depositing aluminum oxide layers 810 and the graphene layers 814.

To promote the tunneling effect, each of the aluminum oxide layers 810 is deposited to have a thickness not thicker than 50 Å, more preferably not thicker than 20 Å. In one embodiment, the temperature for deposition may be maintained at 80° C. Specifically, the aluminum oxide layers 810 are deposited by atomic layer deposition (ALD) processing using trimethylaluminum (TMA), N₂O or other gases (e.g., O₂, O₃, N₂+O₂, CO₂ including oxygen) as precursor. DC pulse of 300 Watt may be applied to the radical reactor at 300 kHz at duty cycle of 50% to generate radicals that are injected onto the surface of the substrate and/or the deposited layer to enhance the deposition of the aluminum oxide layer 810.

Instead of using aluminum oxide, oxides such as SiO₂, ZrO₂, ZnO, TiO₂ or combination thereof may also be used as the material on which graphene or conjugated carbons is deposited. The material on which graphene or conjugated carbons may be formed using ALD or other deposition methods such as molecular layer deposition (MLD). To enhance or facilitate the MLD process, the substrate and/or the deposited layer may be subject to radicals of gases. When semiconductor oxides (e.g., ZnO and TiO₂) having high electric conductivity or oxides (e.g., HfO₂, ZrO₂) exhibiting Poole-Frenkel (P-F) effect are used, these oxides can be thicker than oxides exhibiting F-N tunneling effect. For example, the thickness of oxides with high electric conductivity or oxides exhibiting P-F tunneling effect can be 100 Å to 1,000 Å. A layer of graphene or conjugated carbons can be deposited during or after depositing such oxide layers to form a transparent conducting layer.

To deposit a layer of aluminum oxide, TMA is injected onto the substrate followed by purging by inert gas (e.g., Argon gas) to retain only a single molecular layer of TMA adsorbed on the substrate. Gases such as N₂O, O₂ or O₃ are injected into a radical reactor generate O* radicals. O* radicals are injected onto the substrate to cause reaction with or replacement of CH₃ ligands in TMA molecules to form a layer of aluminum oxide. Generally, 1.6 Å to 1 Å thickness of aluminum oxide layer is deposited per a single pass of TMA injection and O* radical injection as the substrate moves below the injector or the radical reactor at the speed of 50 mm/second to 420 mm/second.

In one embodiment, a deposition device including three reactor assemblies for depositing the aluminum oxide layer of 1 Å to 20 Å and a reactor assembly for depositing a layer of graphene or conjugated carbons is used to form the structure of FIG. 8. The reactor for depositing the layer of graphene or carbon conjugates is provided with a mixture of Argon gas, N₂O gas and C₂H₂ gas. In one embodiment, the flow rate of Argon is 100 sccm, the flow rate of N₂O is 10 sccm and the flow rate of C₂H₂ gas is 10 sccm. As the substrate passes below the reactor, a layer of graphene or conjugated carbons is formed on the substrate.

Experiments were performed to compare material deposited based on the gas provided to the radical reactor for depositing a layer of graphene or conjugated carbons. In the first experiment, only Ar gas was injected into the radical reactor. In the second experiment, a mixture of Ar gas, N₂O gas and C₂H₂ gas was injected into the radical reactor. In the third experiment, a mixture of Ar gas, O₂ gas and C₂H₂ gas was injected into the radical reactor. In the fourth experiment, 2,3-Butylene glycol (C₄H₁₀O₂) and N₂O gas were injected into the radial reactor to deposit a layer of graphene or conjugated carbons.

According to the analysis of the deposited material in each experiment, the density of conjugated carbons was the highest when the mixture of Ar gas, N₂O gas and C₂H₂ gas was used, followed by the case where the mixture of Ar gas, O₂ gas and C₂H₂ gas was used. In the case where 2,3-Butylene glycol (C₄H₁₀O₂) and N₂O gas were injected or in the case where only Argon was injected, the conjugated carbons were virtually non-existent or were very low in concentration.

Hence, it was determined that the use of a mixture gas Ar gas, N₂O gas and C₂H₂ gas or a mixture gas of Ar gas, O₂ gas and C₂H₂ was conducive to depositing a layer of graphene or conjugated carbons.

In one embodiment, a deposition device includes three reactor assemblies for depositing the aluminum oxide layer of thickness thicker than 50 Å (preferably thicker than 100 Å ). The aluminum oxide layer becomes part of a sandwiched insulator/graphene/insulator (IGI) structure for use as encapsulation or gas barrier. The temperature for deposition may be maintained at 80 to 100° C., and a reactor assembly for depositing a layer of graphene or conjugated carbons is used. The reactor is provided with a mixture of Ar gas and N₂O gas. The basic IGI structure for encapsulation is preferably Al₂O₃ of 100 Å of thickness stacked on top of one or two layers of graphene (or conjugated carbons) which in turn is stacked on top of Al₂O₃ of 100 Å thickness. The sandwiched structure including one or two layers of graphene (or conjugated carbons) shows better barrier properties than Al₂O₃ layer of 200 Å thickness without graphene or conjugated carbons.

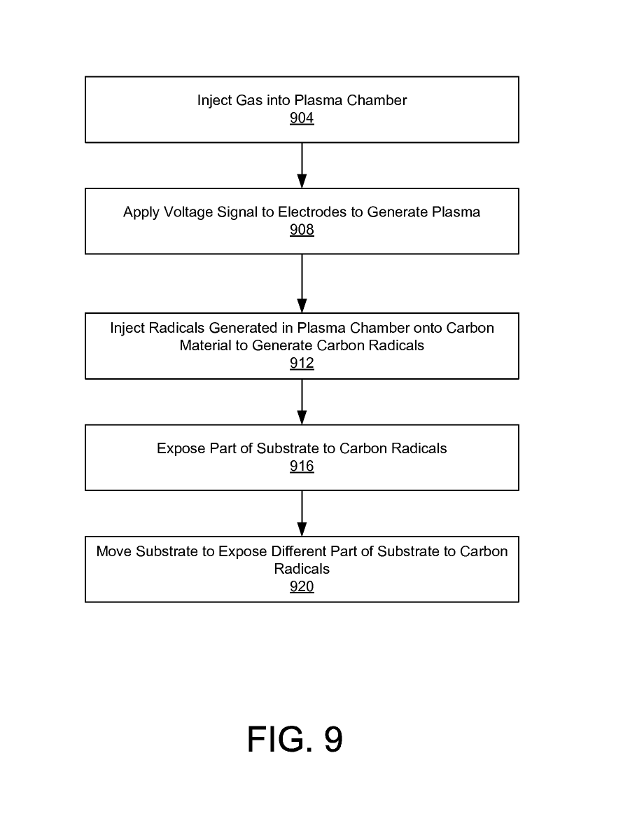

FIG. 9 is flowchart illustrating a process of depositing a layer of graphene or conjugated carbons, according to one embodiment. Gas is injected 904 into plasma chamber formed in a body of the radical reactor.

A voltage signal is applied 908 across two electrodes defining the plasma chamber to generate plasma. The electrical voltage signal may be pulses of voltage signal with a certain duty cycle.

As a result of the plasma, radicals are generated in the plasma chamber. The radicals generated in the plasma chamber are injected 912 onto carbon material to generate carbon radicals. Part of a substrate is exposed 916 to the carbon radicals to deposit a layer of graphene or conjugated carbons.

The substrate is moved 920 to expose different parts of substrate to carbon radicals.

Embodiments advantageously allow deposition of a layer of graphene or conjugated carbons on a surface of a substrate in an efficient and cost-effective manner.

Although the present invention has been described above with respect to several embodiments, various modifications can be made within the scope of the present invention. Accordingly, the disclosure of the present invention is intended to be illustrative, but not limiting, of the scope of the invention, which is set forth in the following claims.

1. A method of depositing a layer of graphene or conjugated carbons, comprising:
injecting radicals of a gas onto a surface of carbon material to generate carbon radicals;
exposing a part of a surface of a substrate to the generated carbon radicals to deposit the layer of graphene or conjugated carbons; and
moving the substrate to expose different parts of the surface of the substrate to the generated carbon radicals.

2. The method of claim 1, wherein the gas comprises an oxygen compound.

3. The method of claim 2, wherein the gas further comprises inert gas.

4. The method of claim 1, wherein the carbon material comprises graphite.

5. The method of claim 1, wherein the conjugated carbons comprise at least one of graphyne, graphane, graphene oxide and carbon nanotubes.

6. The method of claim 1, further comprising discharging excess carbon radicals remaining after exposing to the part of the surface of the substrate.

7. The method of claim 1, further comprising:
injecting gas into a plasma chamber defined by a first electrode and a second electrode; and
applying voltage difference across the first electrode and the second electrode to generate the radicals of the gas.

8. The method of claim 1, wherein a temperature of the substrate is controlled to 100° C. to 500° C.

9. The method of claim 1, further comprising depositing a dielectric layer on the surface, the layer of graphene or conjugated carbons deposited on the dielectric layer.

10. The method of claim 1, further comprising depositing a dielectric layer using atomic layer deposition or molecular layer deposition on the surface of the substrate, the layer of graphene or conjugated carbons deposited on the dielectric layer.

11. An apparatus for depositing a layer of graphene or conjugated carbons, comprising:
a body formed with a plasma chamber for receiving a gas and a path for injecting radicals of the gas generated in the plasma chamber towards a substrate, the body including a first electrode;
a second electrode extending within the plasma chamber, voltage difference applied across the first electrode and the first electrode body to generate the radicals; and
carbon material between the plasma chamber and the substrate, the carbon material exposed to the radicals of the gas to generate carbon radicals, the carbon radicals injected onto the substrate to deposit the layer of graphene or conjugated carbons on a surface of the substrate.

12. The apparatus of claim 11, wherein the gas comprises an oxygen compound.

13. The apparatus of claim 12, wherein the gas further comprises inert gas.

14. The apparatus of claim 11, wherein the carbon material comprises graphite secured to a wall of the body defining a reaction zone.

15. The apparatus of claim 11, wherein the conjugate carbons comprises at least one of graphyne, graphane, graphene oxide and carbon nanotubes.

16. The apparatus of claim 11, wherein the body is further formed with an outlet for discharging excess carbon radicals remaining after exposing to the surface of the substrate.

17. The apparatus of claim 11, wherein voltage difference is applied across the first electrode and the second electrode to generate the radicals of the gas.

18. The apparatus of claim 11, further comprising a temperature controller for maintaining a temperature of the substrate to 100° C. to 500° C.

19. The apparatus of claim 11, further comprising a reactor assembly for depositing a dielectric layer on the surface of the substrate by atomic layer deposition or molecular layer deposition, the layer of graphene or conjugated carbons deposited on the dielectric layer.

20. The method of claim 19, wherein the dielectric layer is deposited on the surface by atomic layer deposition (ALD) or molecular layer deposition (MLD).
